(19) United States
(12) Patent Application Publication
(10) Pub. No.: US 2026/0282851 A1
(43) Pub. Date: Sep. 17, 2026

(54) System and Method for Self-Aligned Multiple Patterning with Process Steps Within a Single Plasma Process Chamber

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 19/080,947

(22) Filed: Mar. 17, 2025

(51) Int. Cl. H01L 21/033; H01J 37/32; H01L 21/311

(52) U.S. Cl. CPC H10P 76/4085; H01J 37/3211; H01J 37/32146; H10P 50/283; H01J 2237/332; H01J 2237/334

(57) ABSTRACT

Disclosed herein is a system and method for executing self-aligned double patterning (SADP) and self-aligned quadruple patterning (SAQP) in situ within a single plasma process chamber. The system integrates atomic layer deposition (ALD), atomic layer etching (ALE), radical-based highly selective etching (HSE), and dry cleaning, eliminating vacuum breaks to reduce cycle time and prevent undesired surface modifications.

### FIELD OF THE INVENTION

The present invention relates to semiconductor manufacturing, and more particularly, to a process system capable of performing multiple patterning steps in situ within a single process chamber to reduce cycle time and prevent unwanted surface modifications during self-aligned double patterning (SADP) and self-aligned quadruple patterning (SAQP).

### BACKGROUND OF THE INVENTION

SADP and SAQP are widely used in semiconductor manufacturing to achieve critical dimension scaling beyond the resolution limits of lithography. These patterning techniques involve multiple process steps, including deposition, etching, selective material removal, and cleaning. Conventionally, these steps are carried out across different process systems, requiring wafer transfers between process systems. This multi-system approach significantly increases cycle time and introduces process variability due to exposure to ambient conditions.

One specific challenge arises when silicon mandrels are used in SADP and SAQP. When wafers are transferred between process systems, exposure to ambient air can lead to unwanted surface changes, such as the formation of native oxide on silicon mandrels. This unintended oxidation can impact subsequent etching and spacer formation, affecting pattern fidelity and overall process performance.

The present invention addresses these challenges by providing a process system that integrates multiple patterning steps within a single chamber, enabling in situ execution of deposition, etching, radical-based highly selective etching (HSE), and dry cleaning. By eliminating vacuum breaks and maintaining a controlled environment throughout the process, the invention reduces cycle time, prevents unwanted surface modifications, and improves process consistency. This approach simplifies SADP and SAQP while enhancing manufacturing efficiency and yield.

### SUMMARY

In some embodiments, a process system is provided for performing self-aligned multiple patterning (SAMP) with process steps executed in situ within a single plasma process chamber. The system enables SADP, SAQP, and spacer-on-spacer (SoS) SAQP while reducing cycle time, process complexity, and the effects of surface exposure caused by vacuum breaks.

The process system includes a plasma process chamber equipped with a plasma source, a gas distribution unit, a substrate-supporting chuck, a bias unit, a pump system, and a controller. The plasma source is operated using a short RF pulse (less than 100 microseconds) to minimize ion effects during the surface modification step of the ALE process while maintaining a high concentration of radicals. The plasma source may comprise multiple coils connected to multiple RF generators. The process system optionally operates in five distinct modes to perform various patterning and cleaning steps:
1. First Operating Mode: Used for surface modification in the atomic layer etching (ALE) process, where ion effects are suppressed by grounding the chuck and/or pulsing the RF power connected to the plasma source.
2. Second Operating Mode: Used for the sputtering step in ALE, where a bias voltage is applied to the chuck to accelerate ions for selective removal of a modified surface layer.
3. Third Operating Mode: Used for atomic layer deposition (ALD) processes, where precursor adsorption and plasma-enhanced reactions enable conformal layer deposition.
4. Fourth Operating Mode: Used for radical-based highly selective etching (HSE), where plasma conditions similar to surface modification are applied to selectively remove material with suppressed ion effects.
5. Fifth Operating Mode: Used for dry cleaning processes, including mask removal and pre-deposition surface preparation or post ALE cleaning, where plasma radicals and/or low-energy ions clean the substrate surface.

The system enables seamless execution of SADP, SAQP, or SoS SAQP by integrating deposition, etching, and cleaning steps within a single chamber. A key advantage of the system is its ability to achieve a near ideal ALE process, characterized by highly selective etching and superior etch profile control. By separating the surface modification and material removal steps, ALE enables precise layer-by-layer etching, minimizing damage to underlying materials. This capability is particularly beneficial for mandrel and spacer etching, ensuring vertical profiles, reduced line edge roughness, and improved uniformity across the wafer. The high selectivity of ALE also enhances etch-stop layer integrity, making it a critical enabler for reliable pattern transfer in SADP, SAQP, and SoS SAQP.

By executing all process steps in situ, the system eliminates the need for wafer transfers between chambers or process systems, reducing cycle time and process complexity. The elimination of vacuum breaks prevents unintended surface modifications, such as native oxide growth on mandrel surfaces, improving pattern fidelity and overall yield.

### BRIEF DESCRIPTIONS OF THE DRAWINGS

FIG. 1A: Illustrates an exemplary plasma process chamber in a first embodiment, featuring short RF pulses for the plasma source.

FIG. 1B: Illustrates an exemplary plasma process chamber in a second embodiment, featuring a switchable blocking capacitor coupled to the bias unit and short RF pulses for the plasma source.

FIG. 2A: Presents a first operating mode of the plasma process chamber, wherein the chamber is used for a surface modification step of the ALE process with suppressed ion effects.

FIG. 2B: Presents a second operating mode of the plasma process chamber, wherein the chamber is used for a sputtering step of the ALE process.

FIG. 2C: Presents a third operating mode of the plasma process chamber, wherein the chamber is used for an ALD process with adsorption steps.

FIG. 2D: Presents a fourth operating mode of the plasma process chamber, wherein the chamber is used for a radical-based HSE process.

FIG. 2E: Presents a fifth operating mode of the plasma process chamber, wherein the chamber is used for a dry cleaning process.

FIG. 3: Illustrates an exemplary flow for SADP with in situ process steps.

FIG. 4: Illustrates an exemplary flow for SAQP with in situ process steps.

FIG. 5: Illustrates an exemplary flow for a SoS SAQP with in situ process steps.

FIG. 6: Illustrates an exemplary flow for SADP using photo resist or its under layers as the mandrel with in situ process steps.

### DETAILED DESCRIPTIONS

To ensure comprehensive understanding, this section delves into detailed embodiments of the present invention. Although specific details are provided for clarity, modifications and variations that align with the subsequent claims are considered within the scope of this disclosure. Conventional methods and components are highlighted to emphasize the distinct features of the invention.

### Terms Used in this Disclosure

Plasma Process Chamber: A vacuum-sealed environment specialized for plasma-based processes, including deposition, etching, selective material removal, and cleaning.
Chuck: A substrate support structure, including electrostatic and vacuum chucks, ensuring stability and uniform clamping during processing.
Gas/Precursor Source: Supplies process gases or precursors, including vaporized materials, ensuring precise composition and flow conditions.
Gas/Precursor Distribution Unit: A system for delivering process gases or precursors, including injectors or showerheads, designed to ensure controlled distribution in the process chamber.
Plasma Source: Components responsible for generating plasma for processing, including inductively coupled plasma (ICP) and capacitively coupled plasma (CCP).
Atomic Layer Etching (ALE): A cyclic process involving alternating surface modification and sputtering steps, providing atomic-scale precision in etching.
Atomic Layer Deposition (ALD): A deposition technique that forms conformal films by sequentially exposing the substrate to alternating precursor and reactant pulses, ensuring uniform layer growth.
Highly Selective Etching (HSE): A radical-based etching process that removes target layers with high selectivity while preserving underlying or adjacent materials.
Dry Cleaning Process: A plasma-based cleaning method that removes contaminants or unwanted material after etching steps or before deposition steps.
Surface Modification Step: The first step in an ALE cycle where reactive radicals chemically modify the substrate surface without material removal.
Sputtering Step: The second step the ALE cycle where ion bombardment physically removes the modified layer.
Radicals: Chemically reactive neutral species, such as halogen, hydrogen, or oxygen radicals, generated in a plasma and used in ALE, HSE and dry cleaning processes.
Sheath: The boundary layer between the plasma and the substrate, regulating ion energy and flux critical for etching and deposition.
Bias Unit: A component generating a bias voltage to accelerate ions toward the substrate during the sputtering step of ALE, enhancing ion bombardment.
Switchable Blocking Capacitor: A circuit element that dynamically activates or deactivates the bias unit, enabling suppressed ion effects during the surface modification step of the ALE and the radical-based HSE step.
Short RF Pulse: A technique applied to the plasma source to suppress ion effects while sustaining a high radical concentration, optimizing ALE surface modification and radical-based etching steps.
RF Power Generator: A device supplying radio frequency energy to sustain plasma in the chamber, enabling material deposition or removal.
Controller: A central unit managing process parameters, plasma conditions, and chamber operations to ensure optimal performance.
Substrate: The base material, typically a silicon wafer, on which semiconductor devices are fabricated.
Mandrel: a temporary structure used in SADP and SAQP processes to define spacer features for patterning.
Spacer: A deposited layer that defines feature patterns in self-aligned multiple patterning techniques such as SADP and SAQP.
Self-Aligned Double Patterning (SADP): A patterning technique where a spacer is deposited on a mandrel, followed by the removal of the mandrel, creating a pitch-doubled pattern used for advanced lithography scaling.
Self-Aligned Quadruple Patterning (SAQP): An extension of SADP by incorporating additional deposition and etching steps, further reducing feature size and enabling higher-density semiconductor structures.
Spacer-on-Spacer (SoS) SAQP: a variation of SAQP where a second spacer is directly formed over a first spacer, simplifying the patterning process.
Self-Aligned Octuple Patterning (SAOP): a patterning technique extending SAQP by incorporating additional deposition and etching steps, achieving even finer feature scaling.

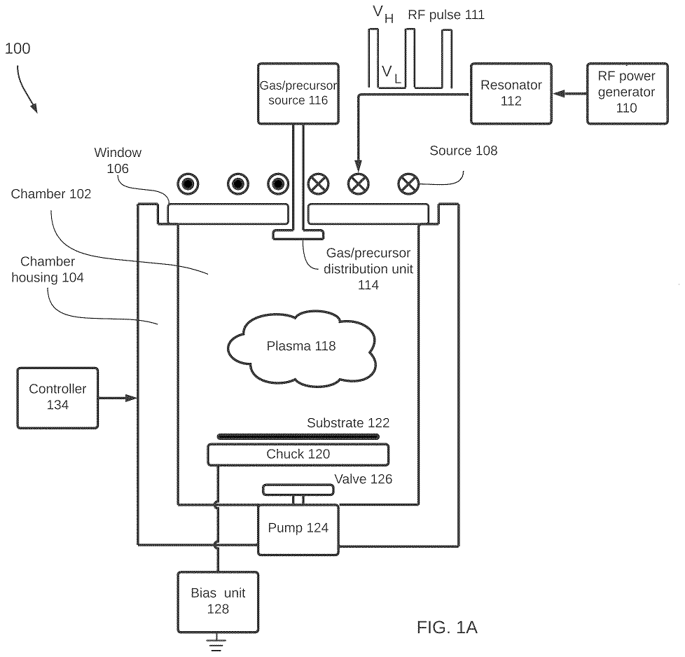

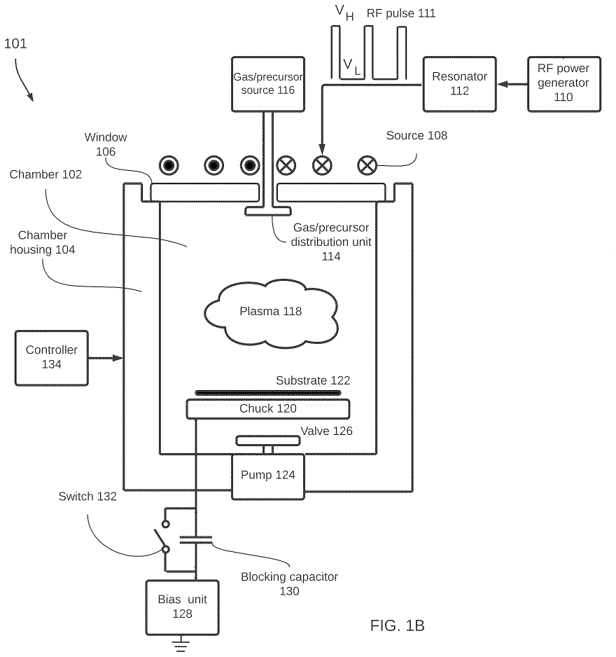

FIG. 1A illustrates a first embodiment of a process system, designated as 100, comprising a plasma process chamber, labeled as 102, coordinated by a controller, referred to as 134. The chamber 102 is enclosed by a chamber housing, indicated as 104, which provides a vacuum environment suitable for plasma processing. The housing 104 may be constructed from materials such as aluminum or quartz, with the aluminum surface optionally treated through anodizing or yttrium oxide coating to enhance resistance to plasma exposure.

A hermetically sealed window, labeled as 106, is positioned atop the chamber housing 104. In some embodiments, the window is made of quartz or other plasma-resistant materials, with its interior surface optionally coated with a plasma-resistant material such as yttrium oxide. Above the window 106, a plasma source, designated as 108, is situated. The plasma source includes a three-turn coil but may have variations in the number of turns, shapes (e.g., cylindrical or conical), or configurations, depending on operational requirements. In some implementations, multiple coils may be used, including a configuration with a center and an edge coil, or another configuration with a center, a middle, and an edge coil. In some other implementations, a coil along a sidewall of the chamber housing 104 may also be included, wherein the part of the sidewall is constructed from a dielectric material such as quartz or ceramic.

In one implementation, the plasma source 108 is connected to a radio frequency (RF) power generator, labeled as 110, via a resonator, identified as 112, to ensure impedance matching with the plasma load in chamber 102. The RF generator 110 can operate at a single frequency or multiple frequencies, including, but not limited to, 100 kHz, 200 kHz, 400 kHz, 2 MHz, 13.56 MHz, 27 MHz, 40 MHz, and 60 MHz. In another implementation, if more than one coil is used, each coil may be driven by a different RF power generator, possibly operated at a distinct frequency. In still some implementations, some coils may share an RF power generator while other coils are coupled to other the RF power generators, respectively.

In some implementations, the RF power is delivered in a pulsed form, represented as 111, modulated by a square wave with a specified duty cycle. This duty cycle, expressed as a percentage, is defined by high (V_{H}) and low (V_{L}) DC voltage levels, with V_{L} being either ground voltage or a nonzero value.

In inductively coupled plasma (ICP) or transformer coupled plasma (TCP) reactors, plasma ignition involves a transition from E mode (electrostatic mode) to H mode (helicon or high-density mode). E mode relies on capacitive coupling with low plasma density, while H mode uses inductive coupling for high plasma density and ionization efficiency. During RF pulsing, if the duty cycle is too low, plasma power may fall below the threshold required to sustain H mode, forcing the plasma to revert to E mode. Repeated transitions between E mode and H mode increase energy consumption and reduce process efficiency. Maintaining minimal sustaining power between pulses keeps the plasma in an “on” state, reducing the time and energy needed to re-establish H mode and ensuring consistent plasma characteristics.

To minimize ion generation while maintaining high radical concentrations, short RF pulses 111 can be designed so that the plasma remains “on” at minimal RF power. This configuration allows the RF power to rapidly achieve the desired high-power state without repeated E-to-H transitions. In some implementations, duration of the RF pulse is less than 100 microseconds.

A gas/precursor distribution unit, labeled as 114, connects to a gas/precursor source, identified as 116, via an aperture in the window 106, ensuring a hermetic seal. The gas/precursor source 116 may supply various process gases and precursors, and the distribution unit 114 may function as an injector or showerhead. In some configurations, the window 106 integrates the gas distribution unit 114 as a showerhead.

Within the chamber 102, a chuck, labeled as 120, supports a substrate, indicated as 122. The chuck 120 may be an electrostatic chuck (ESC) or a vacuum chuck. The chamber 102 is coupled to a pump, labeled as 124, and an associated valve, labeled as 126, to remove unused gases and reaction byproducts, with the withdrawal rate controlled by the valve 126 and the capacity of pump 124.

The plasma generated in the chamber 102 is labelled as 118. The plasma includes electrons, ions and neutrals which further include chemical reactive radicals.

In a second embodiment, labeled as 101, as shown in FIG. 1B, a blocking capacitor, labeled as 130, is included to block direct current (DC) signals, stabilizing the plasma sheath above the substrate 122. This capacitor prevents electron movement to the ground, enabling the accumulation of a negative potential. A parallel switch, labeled as 132, connected to the blocking capacitor 130, allows dynamic control. When the switch 132 is closed, the chuck 120 is grounded via the bias unit 128. When open, the blocking capacitor 130 functions normally. In other configurations, a two-way or series switch (not shown in FIG. 1B) may connect the chuck 120 to either ground or the bias unit 128.

During the ALE surface modification step, the switch 132 bypasses the blocking capacitor 130, preventing sheath formation and suppressing ion effects. In the sputtering step, the switch 132 is open, activating the blocking capacitor 130 to establish a bias for ion acceleration. The controller 134 manages the switch operation via electrical signals, and the switch 132 may include transistors or relays, such as power MOSFETs, or other known mechanisms.

Combining this technique with short pulses of the RF power ensures minimized ion effects for processes such as the ALE surface modification step and radical-based HSE, where a high radical concentration and suppressed ion effects are critical.

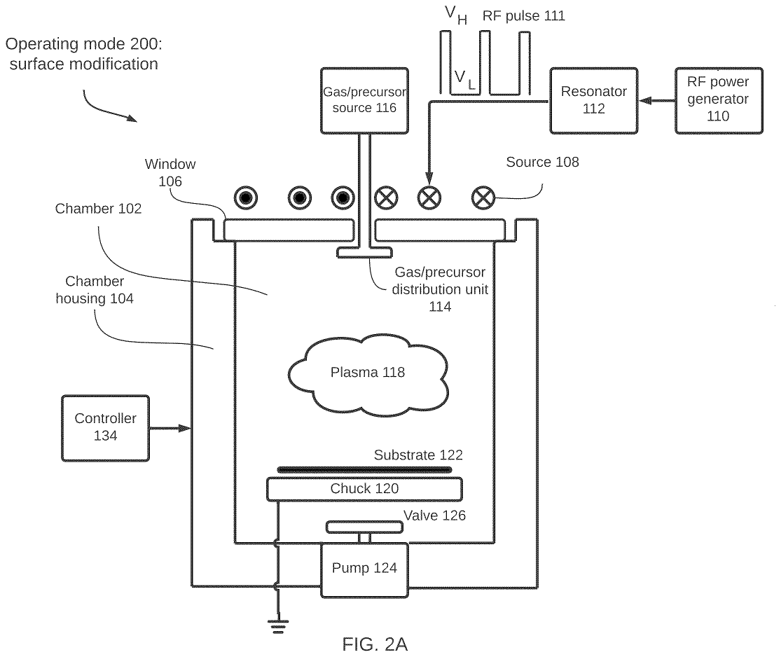

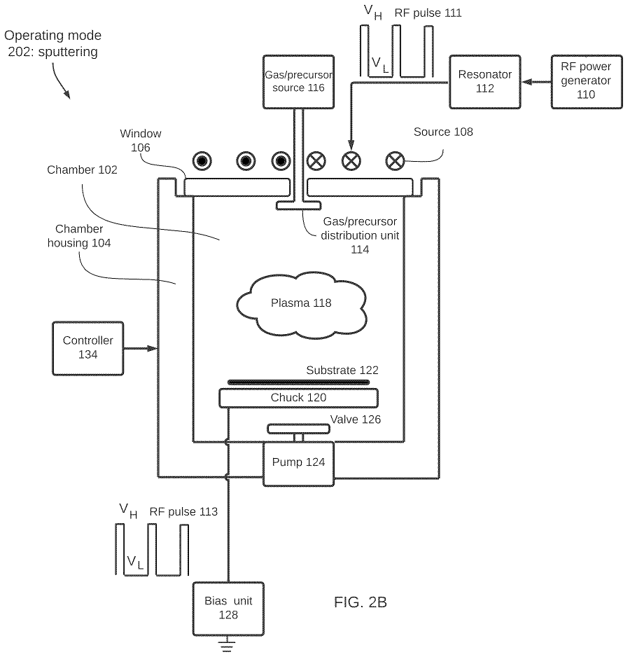

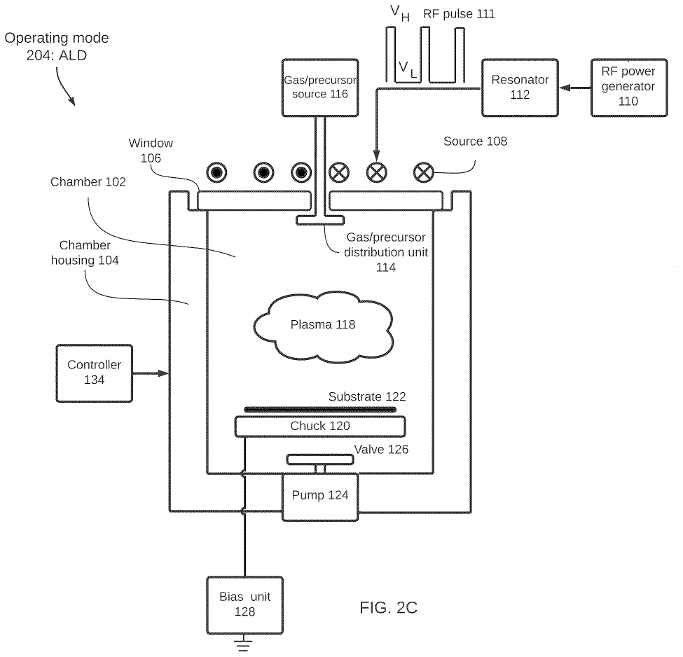

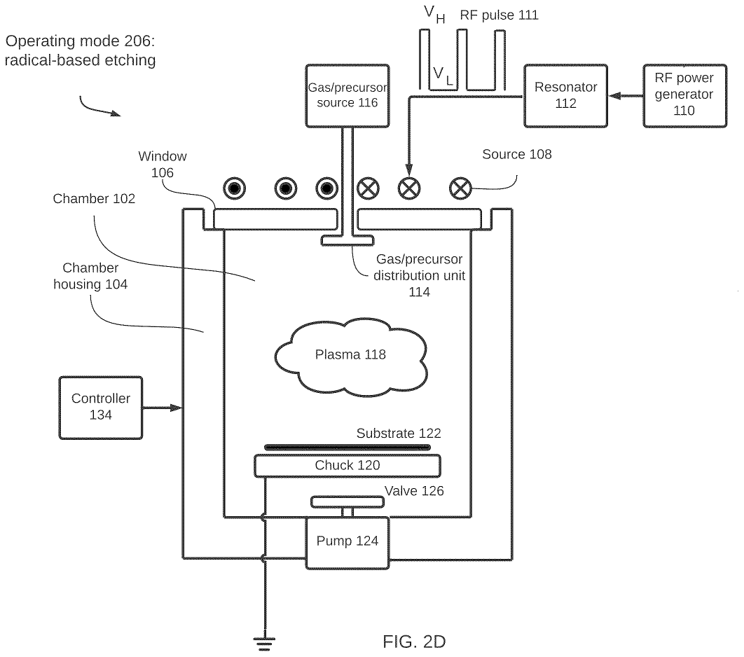

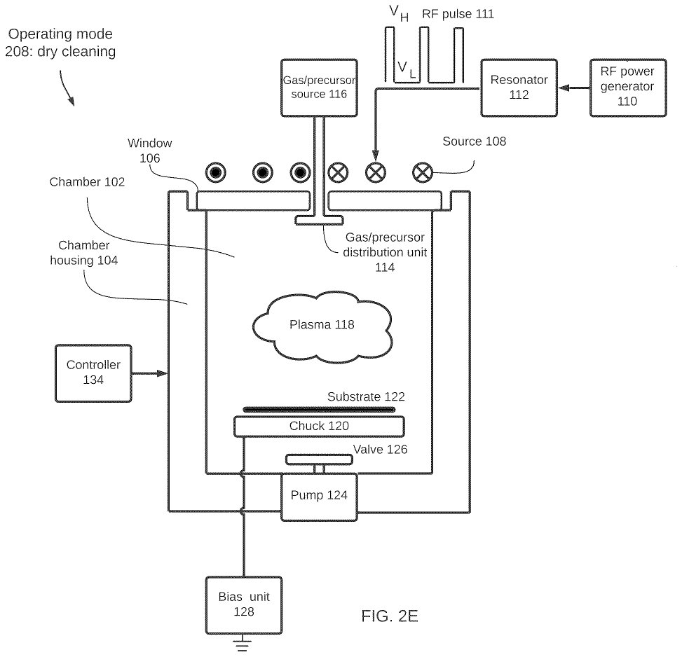

An ALE process comprises a surface modification step and a sputtering step, running in cycles. FIG. 2A illustrates a first operating model (200) of the process system 100, wherein the chamber 102 is used to conduct the surface modification step. It is desirable to minimize ion effects during this step. The chuck 120 is grounded to prevent the formation of the plasma sheath above the substrate 122.

In one implementation, the switch 132 switches off the blocking capacitor 130. In another implementation, the RF pulse 111 is utilized with short pulses, which may be configured to be less than 100 microseconds. In still other implementations, the grounded chuck 120 and the RF pulse 111 may be combined.

FIG. 2B illustrates a second operating mode (202) of the process system 100, wherein the chamber 102 is used to conduct the sputtering step of the ALE process. The bias unit 128 provides a bias voltage to accelerate ions from the plasma 118 toward the surface of the substrate 122. In one implementation, a pulsed RF power 113 is applied to the chuck 120. The RF power 113 and the RF power 111 may be synchronized. In another implementation, the bias unit 128 provides a tailored waveform (not shown in FIG. 2B) to generate ions with a tighter energy distribution.

FIG. 2C illustrates a third operating mode (204) of the process system 100, wherein the chamber 102 is used to conduct an ALD process. The ALD process runs cycles of two consecutive adsorption steps to complete the deposition of a monolayer of a material such as silicon oxide or silicon nitride. In one implementation, the ALD process leverages radicals in the plasma 118 to complete the reactions. For such an implementation, the chamber 102 operates under conditions that minimize ion effects, similar to the surface modification step of the ALE process. In another implementation, a plasma-enhanced ALD process is adopted, wherein both radicals and ions are leveraged. The pulsed RF power may be utilized for the ALD process. It should be noted that the ALD process may be executed at a significantly higher chuck temperature and at a significantly higher chamber pressure than the ALE process.

FIG. 2D depicts a fourth operating mode (206) of the process system 100, wherein the chamber 102 is used to conduct radical-based highly selective etching (HSE). The chamber 102 is operated under requirements similar to the first operating mode (200), with ion effects minimized using the previously described system and method. The radical-based HSE may be operated at a significantly higher temperature and at a significantly higher chamber pressure. The difference between the first and fourth operating modes is that the first mode modifies the surface without material removal, while the fourth mode selectively removes substrate materials. The process gases involved may also differ.

FIG. 2E illustrates a fifth operating mode (208) of the process system 100, wherein the chamber 102 is used to conduct a dry cleaning process. In one implementation, the dry cleaning process is a stripping process employed to remove photoresist or mask materials after the ALE process. In another implementation, the dry cleaning process is used to clean the surface before an ALD process is conducted or after the ALE process. The dry cleaning process may be a radical-based soft etching process, wherein the bias unit 128 is switched off. The dry cleaning process may also leverage low-energy ions, where the bias unit 128 provides a low bias voltage ranging from a few volts to tens of volts.

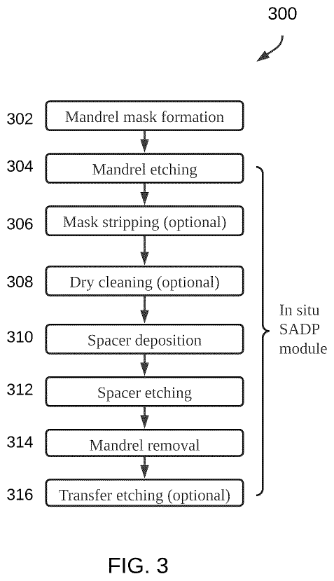

FIG. 3 presents a flowchart for a SADP process, with several process steps conducted within the chamber 102 without breaking the vacuum. Process 300 starts with step 302, in which a mask is formed for the mandrel. In one implementation, the mask may include multiple layers, such as a photoresist layer, a silicon anti-reflective coating (SiARC) layer, and a transfer layer such as a spin-on carbon (SOC) layer. The photoresist layer is exposed in a lithography scanner system and developed in a track system. The mask pattern for the mandrel may be formed through additional etching and trimming processes through the SiARC and SOC layers.

In step 304, mandrel etching is conducted in the chamber 102 using the ALE process, which includes multiple cycles, each comprising a surface modification step operated in the first operating mode (200) and a sputtering step operated in the second operating mode (202). In one implementation, the mandrel material includes silicon. In another implementation, the mandrel material includes carbon. It is desirable that the mandrels exhibit a vertical profile with high selectivity to the underlying layer.

In step 306, the remaining mask materials are optionally removed by operating the chamber 102 in the fifth operating mode (208). In step 308, a dry cleaning step (208) is optionally conducted to prepare the substrate 122 for subsequent steps.

In step 310, a conformal film, such as a silicon oxide layer or a silicon nitride layer, is deposited using the ALD process by operating the chamber 102 in the third operating mode (206). In some implementations, the conformal layer may also be a metal oxide layer.

In step 312, spacers are formed by conducting the ALE etching. The chamber 102 is operated in the first and second operating modes (200 and 202) sequentially in cycles. The ALE process provides high selectivity to etch stop layers, which is important for the SADP process. In some implementations, a deposition step may be added to the ALE process to shape the spacer closer to a rectangular profile. This may introduce an additional operating mode for the chamber 102. The deposition step may or may not be an ALD process.

In step 314, the mandrels are removed by conducting the radical-based HSE process. The chamber 102 is operated in the fourth operating mode (206). For example, oxygen/hydrogen radicals may be used to remove carbon mandrels.

In step 316, the spacer patterns are optionally transferred to the underlying layer using the ALE process. The chamber 102 is operated in the first and second operating modes (200 and 202).

Steps 304 through 316 are conducted within the process chamber 102 without breaking the vacuum. The in situ processes simplify the process flow, reduce cycle time, and improve process performance by eliminating negative effects caused by exposing the substrate to air. For example, native oxide formation can be eliminated.

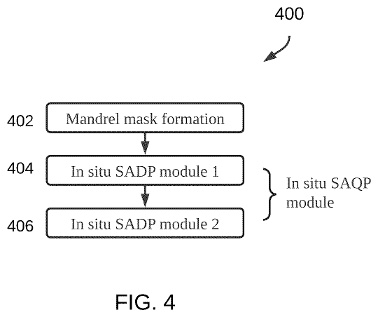

FIG. 4 depicts a flowchart of a self-aligned quadruple patterning (SAQP) process, denoted as 400. After the formation of the mandrel mask in step 402, two consecutive in situ SADP modules, module 1 (404) and module 2 (406), are conducted in chamber 102 without breaking the vacuum. The first spacer in module 404 is used to pattern the second mandrel for the second module 406.

The SAQP process can be extended to self-aligned octuple patterning (SAOP) by adding an additional in situ SADP module by using the second spacer as mandrel 3 (not shown in the Figure).

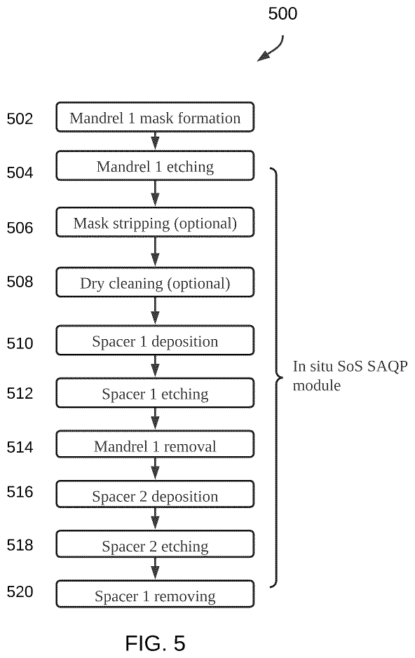

In some implementations, the SAQP process flow can be further simplified by adopting the SoS flow, as depicted in FIG. 5. Process 500 starts with step 502, in which a mask is formed for mandrel 1. In one implementation, the mask may include multiple layers, such as a photoresist layer, a silicon anti-reflective coating (SiARC) layer, and a transfer layer such as a spin-on carbon (SOC) layer. The photoresist layer is exposed in a lithography scanner system and developed in a track system. The mask pattern for the mandrel is formed through additional etching and trimming processes through the SiARC and SOC layers.

In step 504, mandrel 1 etching is conducted in the chamber 102 using the ALE process, which includes multiple cycles, each comprising a surface modification step operated in the first operating mode and a sputtering step operated in the second operating mode. In one implementation, the mandrel material includes silicon. In another implementation, the mandrel material includes carbon. It is desirable for the mandrels to have a vertical profile with high selectivity to the underlying layer.

In step 506, the remaining mask materials are optionally removed by operating the chamber 102 in the fifth operating mode (208). In step 508, a dry cleaning step is optionally conducted to prepare the substrate 122 for subsequent steps.

In step 510, a conformal film, such as a silicon oxide layer or a silicon nitride layer, is deposited using the ALD process by operating the chamber 102 in the third operating mode (204). In some implementations, the conformal layer may also be a metal oxide layer.

In step 512, spacer 1 is formed by conducting the ALE etching. The chamber 102 is operated in the first and second operating modes (200 and 202) sequentially in cycles. The ALE process provides high selectivity to etch stop layers, which is important for the SADP process. A deposition step may be added to the ALE process to shape the spacer closer to a rectangular profile. This may introduce an additional operating mode for the chamber 102. The deposition step may or may not be an ALD process.

In step 514, mandrel 1 is removed by conducting the radical-based HSE process. The chamber 102 is operated in the fourth operating mode (206). For example, oxygen/hydrogen radicals may be used to remove carbon mandrels.

In step 516, another conformal film is deposited on top of spacer 1, which is used as mandrel 2 at this step. In step 518, the ALE process is used to form spacer 2. The spacer material needs to be different from that of spacer 1. For example, if spacer 1 is silicon oxide, spacer 2 may be silicon nitride.

In step 520, spacer 1 (mandrel 2) is removed using the radical-based HSE process. The SoS SAQP process is completed. All steps from 504 to 520 are conducted in situ in the chamber 102 without breaking the vacuum.

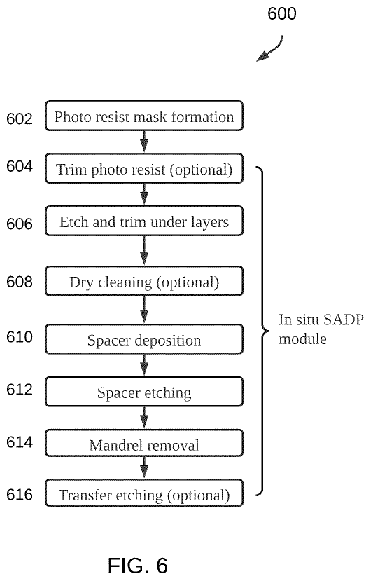

In some SADP process flows, as shown in FIG. 6, the first mandrel is formed during the lithography process. The inventive concept of the present invention readily extends to such cases. Process 600 begins with step 602, where a photoresist mask is formed through a lithography process that includes exposure in a stepper or scanner, followed by a development step typically conducted in a track system. In step 604, after the substrate is loaded onto the chuck of the process system, the critical dimension of the photoresist mask may be optionally trimmed by operating chamber 102 in a radical-based HSE process. In step 606, underlayers of the photoresist may be etched using the ALE process. In one implementation, these underlayers include a SiARC layer and an SOC layer, while in another implementation, the underlayers include Advanced Patterning Films (APF) deposited via a chemical vapor deposition (CVD) process. The photoresist mask may then be stripped by operating chamber 102 in a dry cleaning process mode or a radical-based HSE mode. The underlayer serving as the mandrel may optionally be further trimmed in chamber 102 using either the radical-based HSE process or the dry cleaning process. One or a combination of the remaining layers may be used as the first mandrel before the ALD process is applied in situ to deposit the conformal layer for the spacers. All subsequent process steps, from step 608 to step 616, follow the SADP process flow described in FIG. 3 and are executed in the same process chamber without breaking vacuum.

In all SAMP process flows described in this disclosure, the defined lines produced through SAMP techniques may need to be cut to form shorter lines. Additional process steps, including lithography steps, are required to complete the full SAMP process after the substrate is withdrawn from the process system. In some implementations, the substrate may need to be withdrawn from the chamber between process steps in processes 300, 400, 500, and 600. All such variations fall within the inventive concept of this disclosure as long as more than one operating mode is utilized to complete the multiple patterning process flow.

In some other implementations, the defined lines may need to undergo a tone inversion process to define patterns for trenches, such as those used in logic interconnect processes. This process enables the conversion of line patterns into trench structures, facilitating their integration into interconnect fabrication. The tone inversion step may involve additional deposition, etching, or selective material removal processes, depending on the specific patterning requirements.

1. A plasma process chamber operated in a vacuum environment, comprising:
a plasma source connected to one or more RF power generators, configured to generate plasma within the chamber;
a chuck configured to support a substrate;
a bias unit connected to the chuck, configured to generate a bias voltage;
a gas/precursor distribution unit configured to deliver process gases or precursors; and
a controller configured to execute a portion of a SADP or SAQP process flow within the chamber without breaking the vacuum environment, including:
operating the chamber to conduct an ALE process, comprising a surface modification step and a sputtering step, wherein the chamber is configured to minimize ion effects during the surface modification step;
operating the chamber to conduct an ALD process; and
operating the chamber to conduct a radical-based HSE process.

2. The chamber of claim 1, wherein the controller further operates the chamber to conduct a dry cleaning process, which is executed without breaking the vacuum.

3. The chamber of claim 2, wherein the dry cleaning process is used to remove residuals after the ALE process.

4. The chamber of claim 1, wherein the plasma source includes one or more coils.

5. The chamber of claim 1, wherein each RF power generator operates at distinct frequencies.

6. The chamber of claim 1, wherein the ion effects are suppressed by employing a switchable blocking capacitor coupled to the bias unit, which is deactivated during the surface modification step of ALE and the radical-based HSE process.

7. The chamber of claim 1, wherein the ion effects are suppressed by applying pulsed RF power to the plasma source.

8. The chamber of claim 7, wherein the duration of the pulsed RF power is less than 100 microseconds.

9. The chamber of claim 1, wherein the ALE process is used to form mandrels during the SADP or SAQP process flows.

10. The chamber of claim 9, wherein the mandrels comprise a carbon-containing material or a silicon-containing material.

11. The chamber of claim 1, wherein the ALD process is used to form a conformal film, which is subsequently used to form spacers via the ALE process.

12. The chamber of claim 11, wherein the spacers comprise one of the following materials:
silicon oxide, silicon nitride, or a metal oxide.

13. The chamber of claim 1, wherein the radical-based HSE process is used to remove the mandrel after spacer formation.

14. The chamber of claim 1, wherein the radical-based HSE process is used to remove a mask layer after mandrel formation.

15. A self-aligned multiple patterning process, comprising:
providing a plasma process chamber with a vacuum environment;
etching through a mask layer to form mandrels using an ALE process;
optionally removing the mask layer using a radical-based HSE process;
optionally cleaning the surface of the substrate using a dry cleaning process;
depositing a conformal layer using an ALD process; and
etching to form spacers using the ALE process,
wherein the ALE, ALD, radical-based HSE, and dry cleaning processes are conducted within the plasma process chamber without breaking the vacuum.

16. The process of claim 15, wherein the mask is a photoresist, and the mandrels are underlayers of the photoresist.

17. The process of claim 15, wherein the mandrels include silicon or carbon.

18. The process of claim 15, wherein the self-aligned multiple patterning process includes SADP, SAQP, and SAOP.

19. The process of claim 15, wherein the plasma process chamber is configured to suppress ion effects during the surface modification step of the ALE process.

20. A SAQP process, comprising:
providing a plasma process chamber with a vacuum environment;
etching through a mask layer to form mandrels using an ALE process;
optionally removing the mask layer using a radical-based HSE process;
optionally cleaning the surface of the substrate using a dry cleaning process;
depositing a first conformal layer using an ALD process;
etching to form the first spacers using the ALE process;
removing the mandrels using the radical-based HSE process;
depositing a second conformal layer using the ALD process;
etching to form the second spacers using the ALE process; and
removing the first spacers using the radical-based HSE process,
wherein the ALE, ALD, radical-based HSE, and dry cleaning processes are conducted within the plasma process chamber without breaking the vacuum.
